(19) United States
(12) Patent Application Publication
(10) Pub. No.: US 2019/0249923 A1
(43) Pub. Date: Aug. 15, 2019

(54) METHODS AND APPARATUS TO PROVIDE CLOSED LOOP CONTROL IN A SOLAR CELL PRODUCTION SYSTEM

(71) Applicant: Illinois Tool Works Inc., Glenview, IL (US)

(72) Inventors: Daniel M. Ruf, Minneapolis, MN (US); Erik R. Anderson, Lakeville, MN (US); Roy Kearns Ball, Austin, MN (US)

(21) Appl. No.: 16/274,997

(22) Filed: Feb. 13, 2019

Related U.S. Application Data
(60) Provisional application No. 62/630,910, filed on Feb. 15, 2018.

(51) Int. Cl. F27D 19/00; H01L 31/18; H02S 50/10

(52) U.S. Cl. CPC F27D 19/00; H01L 31/18; F27D 2019/0034; F27D 2019/0056; F27D 2019/0059; H02S 50/10

(57) ABSTRACT

Methods and apparatus to provide closed loop control in a solar cell production system are disclosed. An example solar cell production system includes: a firing furnace comprising a plurality of zones and a belt configured to transport photovoltaic cells through a sequence of the plurality of zones, the zones comprising firing elements configured to fire a metallization layer of photovoltaic cells by heating ambient air in the zones to respective temperatures; a cooling chamber configured to cool the photovoltaic cells; a photovoltaic cell tester configured to measure a property of the photovoltaic cells after cooling of the photovoltaic cells in the cooling chamber; and control circuitry configured to control firing elements based on the property of the photovoltaic cells measured by the photovoltaic cell tester.

### RELATED APPLICATIONS

This patent claims priority to U.S. Provisional Patent Application Ser. No. 62/630,910, filed Feb. 15, 2018, entitled “METHODS AND APPARATUS TO PROVIDE CLOSED LOOP CONTROL IN A SOLAR CELL PRODUCTION SYSTEM.” The entirety of U.S. Provisional Patent Application Ser. No. 62/630,910 is incorporated herein by reference.

### BACKGROUND

This disclosure relates to solar cell production and, more particularly, to methods and apparatus to provide closed loop control in a solar cell production system.

Photovoltaic cell production involves multiple steps, including depositing the materials and firing the deposited materials in a furnace. The properties of certain types of photovoltaic cells are closely related to the firing temperature of the photovoltaic cells. The firing step is typically the final step in the production process, and also has a substantial effect on the performance of the finished photovoltaic cell.

### SUMMARY

Methods and apparatus to provide closed loop control in a solar cell production system are disclosed, substantially as illustrated by and described in connection with at least one of the figures, as set forth more completely in the claims.

### DRAWINGS

These and other features, aspects, and advantages of the present disclosure will become better understood when the following detailed description is read with reference to the accompanying drawings in which like characters represent like parts throughout the drawings, wherein:

FIG. 1 is a block diagram of an example solar cell production system including closed-loop control of photovoltaic cell firing profiles, in accordance with aspects of this disclosure.

FIG. 2 is a side plan view of an example of the firing furnace of FIG. 1.

FIG. 3 is a block diagram of an example implementation of the furnace controller and/or the tester controller of FIG. 1.

FIG. 4 is a flowchart representative of example machine readable instructions 400 which may be executed by the example furnace controller of FIG. 1 to control a heating profile of the firing furnace based on feedback from the tester controller.

FIG. 5 is a flowchart representative of example machine readable instructions which may be executed by the example furnace controller of FIG. 1 to modify a firing profile based on the feedback from the cell tester.

FIG. 6 is a flowchart representative of example machine readable instructions which may be executed by the example tester controller of FIG. 1 to provide feedback about a measured property of photovoltaic cells to the furnace controller.

The figures are not necessarily to scale. Where appropriate, similar or identical reference numbers are used to refer to similar or identical components.

### DETAILED DESCRIPTION

Conventional photovoltaic cell production systems enable operators to define the temperature at which the furnace is to heat the photovoltaic cell. However, due to the high sensitivity of performance to firing temperature and the large number of combinations of firing temperatures and dwell times, making improvements to a firing method may be difficult.

Additionally, conventional techniques of trial-and-error to search for improvements in cell performance are laborious, time-intensive, and costly, and involve reducing the output of a cell production line during the trial-and-error process.

Disclosed example photovoltaic cell production systems and methods increase the performance that can be gained from photovoltaic cells in the firing stage. In some examples, a photovoltaic cell tester provides feedback about one or more measured properties of the fired cells to a controller of the firing furnace. Using the feedback, the controller may automatically control the temperatures used in the firing furnace. For example, the controller may make adjustments to individual heating zones of the firing furnace based on feedback indicating that the changes will improve the cell properties.

The terms “photovoltaic cell” and “solar cell” are used interchangeably throughout this patent.

Disclosed example photovoltaic cell production systems include a firing furnace, a photovoltaic cell tester, and control circuitry. The firing furnace has a plurality of zones and a belt configured to transport photovoltaic cells through a sequence of the plurality of zones, in which the zones include firing elements to fire a metallization layer of photovoltaic cells by heating the photovoltaic cells in the zones. The photovoltaic cell tester measures a property of the photovoltaic cells. The control circuitry controls the firing elements based on the property of the photovoltaic cells measured by the photovoltaic cell tester.

In some examples, the control circuitry: controls the firing elements based on a first heating profile for firing a first set of the photovoltaic cells, in which the first heating profile defining a first set of the respective temperatures of the zones; controls the firing elements based on a second heating profile for firing a second set of the photovoltaic cells, in which the second heating profile defining a second set of the respective temperatures of the zones; receives first information representative of the property of the first set of photovoltaic cells from the photovoltaic cell tester; receives second information representative of the property of the first set of photovoltaic cells from the photovoltaic cell tester; and determines a third heating profile based on the first information, the second information, the first heating profile, and the second heating profile. In some such examples, the control circuitry correlates the first information to the first set of the photovoltaic cells based on at least one of a travel speed of the belt, a distance from the firing furnace to the photovoltaic cell tester, a belt stop signal, a belt start signal, or a positive identification of the first set of the photovoltaic cells received from at least one of the photovoltaic cell tester, the firing furnace, or the cooling chamber.

In some example systems the control circuitry controls the firing elements based on a heating profile for firing a first set of the photovoltaic cells, the heating profile defining a set of the respective temperatures of the zones determined based on respective temperature measurements of the zones. Some examples further include thermocouples configured to measure the temperatures of the zones based on a combination of radiant heating and convective heating. In some examples, the property of the photovoltaic cells measured by the photovoltaic cell tester is at least one of an average value of the property for the photovoltaic cells or a statistical variance of the property for the photovoltaic cells.

In some examples, the photovoltaic cell tester measures a plurality of properties of the photovoltaic cells, the plurality of properties including at least one of a cell conversion efficiency, an open-circuit voltage, a short-circuit current, a maximum cell output power, a cell output voltage at the maximum cell power output, a cell output current at the maximum cell power output, a fill factor, a cell diode property, a cell series resistance, or a cell shunt resistance. Some example systems further include a cooling chamber, and the photovoltaic cell tester measure the property of the photovoltaic cells after the photovoltaic cells are cooled by the cooling chamber. In some examples, the firing elements include at least one of radiant heaters or convective heaters.

Disclosed example photovoltaic cell firing furnaces include multiple zones having firing elements configured to fire a metallization layer of photovoltaic cells by heating the photovoltaic cells in the zones; a belt configured to transport photovoltaic cells through a sequence of the plurality of zones; and control circuitry receives feedback information comprising a measured property of the photovoltaic cells and controls the firing elements based on the property of the photovoltaic cells measured by the photovoltaic cell tester.

In some example firing furnaces, the feedback includes, for the photovoltaic cells, at least one of cell conversion efficiency, open-circuit voltage, short-circuit current, maximum cell output power, cell output voltage at the maximum cell power output, cell output current at the maximum cell power output, fill factor, cell diode properties, cell series resistance, or cell shunt resistance. In some examples, the control circuitry: controls the firing elements based on a first heating profile for firing a first set of the photovoltaic cells, in which the first heating profile defining a first set of the respective temperatures of the zones; controls the firing elements based on a second heating profile for firing a second set of the photovoltaic cells, in which the second heating profile defining a second set of the respective temperatures of the zones; receives first information representative of the property of the first set of photovoltaic cells from a photovoltaic cell tester; receives second information representative of the property of the first set of photovoltaic cells from the photovoltaic cell tester; and determines a third heating profile based on the first information, the second information, the first heating profile, and the second heating profile.

In some example photovoltaic cell firing furnaces, the control circuitry correlates the first information to the first set of the photovoltaic cells based on at least one of a travel speed of the belt, a distance from the firing furnace to the photovoltaic cell tester, a belt stop signal, a belt start signal, or a positive identification of the first set of the photovoltaic cells received from at least one of the photovoltaic cell tester, the firing furnace, or the cooling chamber.

Disclosed example photovoltaic cell testers include a test fixture to measure a property of a fired photovoltaic cell, and control circuitry to transmit the measured property to a photovoltaic cell firing furnace as feedback information associated with the fired photovoltaic cell.

In some example photovoltaic cell testers, the test fixture measures at least one of cell conversion efficiency, open-circuit voltage, short-circuit current, maximum cell output power, cell output voltage at the maximum cell power output, cell output current at the maximum cell power output, fill factor, cell diode properties, cell series resistance, or cell shunt resistance as the property.

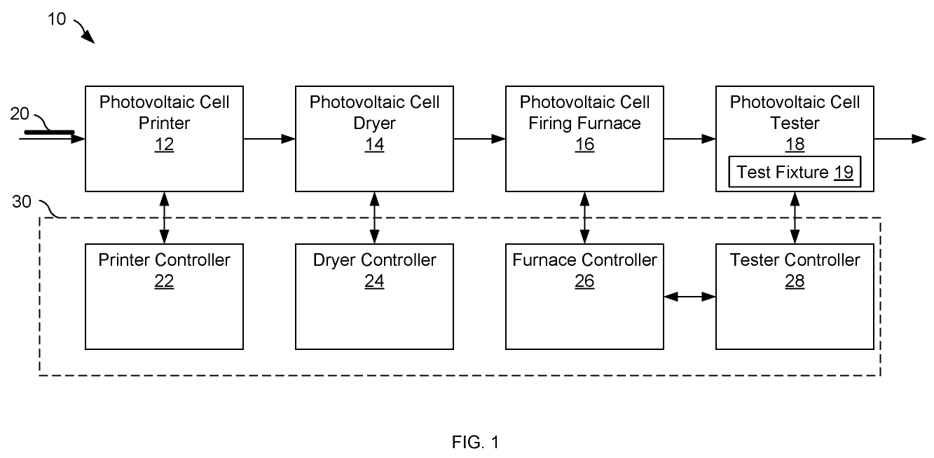

FIG. 1 is a block diagram of an example solar cell production system 10 including closed-loop control of photovoltaic cell firing profiles. The example system 10 of FIG. 1 includes a photovoltaic cell printer 12, a photovoltaic cell dryer 14, a photovoltaic cell firing furnace 16, and a photovoltaic cell tester 18. While one printer 12 and one dryer 14 are illustrated in FIG. 1, the production system 10 may include any number of sets of printers and dryers, based on the photovoltaic cell manufacturing process used and the desired resulting photovoltaic cells.

The photovoltaic cell printer 12 receives substrates 20 and prints one or more layers of material onto the substrates 20 in the desired patterns. The photovoltaic cell dryer 14 receives the substrates 20 onto which the material has been printed, and dries the materials.

At the conclusion of printing and drying, the photovoltaic cell firing furnace 16 fires the substrates and the printed material to raise a temperature of the photovoltaic cell to a desired temperature. Because the properties of certain types of photovoltaic cells are closely related to the firing temperature (as mentioned above), the example photovoltage cell firing furnace 16 may include features to closely control the temperatures to which the photovoltaic cells are exposed. The example photovoltaic cell firing furnace 16 may further cool the photovoltaic cells so that the fired photovoltaic cells can be tested and/or handled shortly following firing.

The example photovoltaic cell tester 18 receives some or all of the completed photovoltaic cells. The tester 18 includes one or more test fixtures 19 to measure one or more properties of the completed (e.g., fired) photovoltaic cells. Example properties that may be measured include cell conversion efficiency, open-circuit voltage, short-circuit current, maximum cell output power, cell output voltage at the maximum cell power output, cell output current at the maximum cell power output, fill factor, cell diode properties, cell series resistance, and/or cell shunt resistance. Based on the properties measured by the tester 18, the photovoltaic cells may be sorted for different applications and/or discarded.

The example system 10 further includes a printer controller 22, a dryer controller 24, a furnace controller 26, and a tester controller 28. In some examples, one or more of the printer controller 22, the dryer controller 24, the furnace controller 26, and the tester controller 28 are combined into one or more computing systems 30 that are in communication with the photovoltaic cell printer 12, the photovoltaic cell dryer 14, the photovoltaic cell firing furnace 16, and/or the photovoltaic cell tester 18. In other examples, one or more of the printer controller 22, the dryer controller 24, the furnace controller 26, and the tester controller 28 are integrated into respective ones of the photovoltaic cell printer 12, the photovoltaic cell dryer 14, the photovoltaic cell firing furnace 16, and/or the photovoltaic cell tester 18.

The example printer controller 22 controls the operation of the photovoltaic cell printer 12 and/or provides information about the operations of the photovoltaic cell printer 12 (e.g., the composition, thicknesses, and/or patterns of the materials printed by the printer 12) to the dryer controller 24, the furnace controller 26, and/or the tester controller 28. The example dryer controller 24 controls the operation of the photovoltaic cell dryer 14 and/or provides information about the operations of the photovoltaic cell printer 12 to the photovoltaic cell printer 12, the furnace controller 26, and/or the tester controller 28.

The example furnace controller 26 controls the operation of the firing furnace 16, such as the heating profiles (e.g., firing temperatures and/or firing dwell time), cooling temperatures (e.g., cooling temperatures and/or dwell time), and/or any other operation of the firing furnace. As described in more detail below, the example furnace controller 26 may control temperatures of individual upper and/or lower firing zones to achieve a particular firing temperature in the photovoltaic cells.

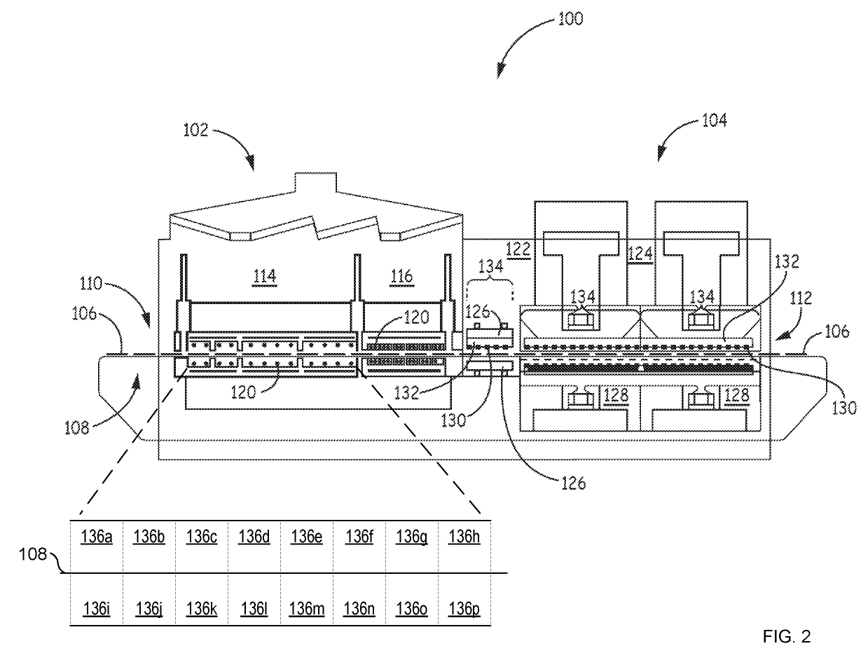

FIG. 2 is a side plan view of an example firing furnace 100 having a heating chamber 102 and a cooling chamber 104, where light annealing is integrated into the cooling chamber 104 but not the heating chamber 102. The example firing furnace 100 may be used to implement the photovoltaic cell firing furnace 16 of FIG. 1.

The furnace 100 shown in FIG. 2 is suitable for use in the firing of metal contacts on photovoltaic devices (such as solar cells) 106. Wafers of photovoltaic cells (also referred to herein as “wafers” or “solar cells”) 106 are transported by a conveyor 108 (e.g., a belt) into an entry 110 formed in the firing furnace 100. After processing, the wafers 106 are transported by the conveyor 108 out of an exit 112 formed in the firing furnace 100. More specifically, in the exemplary embodiment shown in FIG. 2, wafers 106 pass through the entry 110 into the heating chamber 102, then pass through the heating chamber 102 and the cooling chamber 104, and then are conveyed out of the furnace 100 through the exit 112.

Although the following description refers to a single conveyor 108 for ease of explanation, it is to be understood that one, two, or more parallel conveyors 108 can be used at the same time in the same furnace 100. Each separate conveyor 108 is also referred to as a “lane.” In one implementation, the furnace 100 and the conveyor 108 are configured so that each conveyor 108 (and the solar cells 106 thereon) are thermally isolated from one another in order to reduce lane-to-lane influence.

As noted above, the furnace 100 is used for the firing of metal contacts on photovoltaic cells 106. Front and back side metal contacts of photovoltaic cells 106 are initially formed by an electrically conductive metallized paste or ink that is applied, for example, by a screen printing, inkjet spray or aerosol spray process to silicon wafers. Commonly, the front side contact extends in a grid pattern, and the backside contact extends continuously.

After the metallized paste has been applied to the silicon wafers 106, the wafers 106 are dried. The wafers 106 are dried in order to remove any remaining volatile organic compounds (VOCs) (for example, solvent) used in the screen-printing or other paste-application processes.

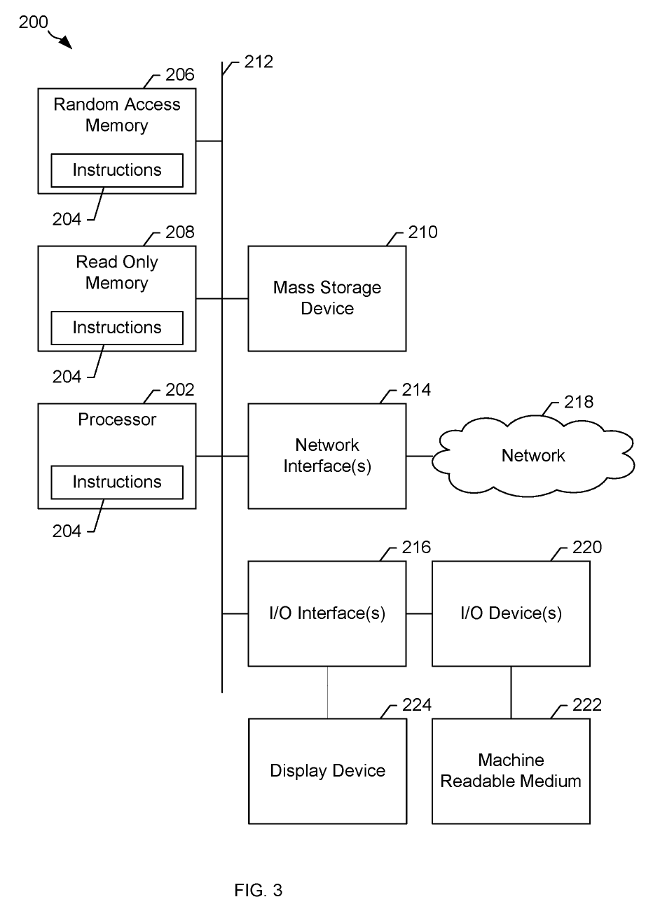

In the exemplary embodiment shown in FIG. 2, the solvent removal is decoupled from binder burnout to improve binder retention. This is done by drying the silicon wafers 106 in a heating chamber that is separate from the heating chamber in which the binder burnout is performed. In one example, this is done by using a separate drying furnace (such as a continuous infrared drying furnace) (not shown in FIG. 2) that feeds into the firing furnace 100 shown in FIG. 2. In an alternative embodiment described below in connection with FIG. 3, the drying furnace is integrated with the firing furnace 100.

In the exemplary embodiment shown in FIG. 2, the heating chamber 102 of the firing furnace 100 includes two heating sections 114 and 116. It is to be understood, however, that a different number of heating sections can be used.

In the exemplary embodiment shown in FIG. 2, the first heating section 114 is configured for binder burn out (and is also referred to here as the “binder-burn-out heating section” 114). In this exemplary embodiment, the second heating section 116 is configured for firing the metallization layers of the solar cells 106 (and is also referred to here as the “metallization heating section” 116). In the particular embodiment shown in FIG. 2, the furnace 100 is configured to thermally decouple the binder-burn-out heating section 114 from the metallization heating section 116 so that each section 114 and 116 can be independently controlled and optimized for each of the respective process objectives.

Exhaust ducts are used to thermally decouple each of the heating sections 114 and 116 from each other and from the exterior environment in the case of the binder-burn-out heating section 114 and from the cooling chamber 104 in the case of the metallization heating section 116. The exhaust ducts are also used to vent out of the furnace 100 any off-gases produced while the wafers 106 pass through the furnace 100.

In the exemplary embodiment shown in FIG. 2, each section 114 and 116 includes multiple pairs of infrared (IR) lamps 120, where one “upper” IR lamp 120 of each pair is located above the conveyor 108 and the other “lower” IR lamp 120 of each pair is located below the conveyor 108 directly opposite the corresponding upper IR lamp 120.

In one implementation, the upper and lower IR lamps 120 can be separately controlled in order to provide independent control and optimization of conditions in the top and bottom regions of the heating sections 114 and 116 (for example, because different metal pastes are used on the top and bottom surfaces of the solar cells 106).

In the exemplary embodiment shown in FIG. 2, the heating chamber 102 includes two heating sections 114 and 116, where each of the sections 114 and 116 can be independently controlled (for binder burn out in the case of the section 114 and for firing the metallization layer in the case of section 116). It is to be understood, however, that the heating chamber 102 can be configured to have a different number of sections. Also, one or more of the sections of the heating chamber 102 can be further subdivided into smaller zones or microzones, where each such zone or microzone can be independently controlled to provide additional control over the heating in the heating chamber 102.

In the exemplary embodiment shown in FIG. 2, the cooling chamber 104 of the firing furnace 100 includes two cooling sections 122 and 124. It is to be understood, however, that a different number of cooling sections can be used.

In the exemplary embodiment shown in FIG. 2, the first cooling section 122 uses radiant cooling to cool wafers 106 that pass through the first cooling section 122, and the second cooling section 124 uses convection cooling to cool wafers 106 that pass through the second cooling section 124. The first cooling section 122 is also referred to here as the “radiant” cooling section 122, and the second cooling section 124 is also referred to here as the “convective” cooling section 124.

In the exemplary embodiment shown in FIG. 2, the radiant cooling section 122 includes a pair of cooling walls 126. One of the cooling walls 126 is positioned above the conveyor 108, and the other one of the cooling walls 126 is positioned below the conveyor 108. In the exemplary embodiment shown in FIG. 2, the cooling walls 126 are water-cooled. Cooled water is circulated through pipes (or other passages) that are in thermal contact with the cooling walls 126. It is to be understood, however, that the radiant cooling may be implemented in other ways.

The silicon wafers 106 that exit the heating chamber 102 and pass through the radiant cooling section 122 are cooled by radiant heat transfer from the wafers 106 to the cooling walls 126 and the water flowing through the pipes.

In the exemplary embodiment shown in FIG. 2, the convective cooling section 124 includes two sub-sections 128. Each of the convective cooling sub-sections 128 includes one or more supply fans that draw air into the upper part of that cooling sub-section 128 and causes the air to flow down towards the conveyor 108 and to pass the wafers 106. The supply air may be sourced from a recirculation duct or from one or more air intakes. Some of the air contacts the surface of the passing wafers 106 as it flows downward, thereby heating the flowing air. The air then flows below the conveyor 108 and the passing wafers 106. Each convective cooling sub-section 128 also includes one or more exhaust fans that draw the flowing air away from the wafers 106. The exhaust fans may expel the air into the environment, to a filter or oxidizer, and/or to a return duct for recirculation of the air back to supply ducts.

In the embodiment shown in FIG. 2, a respective heat exchanger is positioned in each sub-section 128 below the conveyor 108. Air flowing over and around the passing wafers 106 is heated. Heat from the air flowing past the heat exchanger is transferred to the heat exchanger. This cools the air before it is drawn into the return duct and re-circulated into the upper part of the corresponding sub-section 128.

It is to be understood that the particular embodiment of the heating and cooling chambers 102 and 104 shown in FIG. 2 are merely exemplary. The heating and cooling chambers 102 and 104 can be implemented in other ways. For example, the cooling chamber 104 may be omitted, and the wafers 106 cooled via convection after exiting the heating chamber 102.

One or more sections 122 and 124 of the cooling chamber 104 include lights 130 for performing light annealing of the solar cell wafers 106 passing through the cooling chamber 104.

The purpose of light annealing is to reduce the effect of light induced degradation (LID) that occurs in the solar cells 106. Traditionally, this light anneal has involved exposing completed solar cells to intense light at an elevated temperature in a separate, standalone process where the intense illumination occurs, at least in part, in a heating chamber of a furnace.

However, with the co-firing furnace 100 described here in connection with FIG. 2, light annealing to reduce the effects of LID is integrated into the cooling chamber 104 of the co-firing furnace 100. Light annealing is not performed in the heating chamber 102 of the co-firing furnace 100. Instead, residual heat from the heating chamber 102 is used to achieve the required elevated temperature for light annealing in the cooling sections 122 and 124 of the cooling chamber 104. Also, in this exemplary embodiment, a hydrogen source is not present in the cooling chamber 104; instead, light annealing is performed in ambient air.

In the exemplary embodiment shown in FIG. 2, an array of lights 130 is positioned in both the radiant cooling section 122 and the convective cooling section 124 of the cooling chamber 104 but not in the heating chamber 102.

In the exemplary embodiment shown in FIG. 2, for each of the cooling sections 122 and 124, the lights 130 comprise light emitting diodes (LEDs) that are mounted on a water-cooled plate 132. Cooled water is circulated through pipes (or other passages) that are in thermal contact with the plate 132. The plate 132 is water cooled in order to remove heat generated by the LEDs 130 and any heat that is transferred to the LEDs 130 and plates 132 by the passing solar cells 106.

In the exemplary embodiment shown in FIG. 2, one plate 132 with LEDs 130 mounted to it is positioned within the radiant cooling section 122, and another plate 132 with LEDs 130 mounted to it is positioned with the convective cooling section 124. However, it is to be understood multiple plates 132 with LEDs 130 mounted to them can be positioned within the radiant cooling section 122 or the convective cooling section 124. Also, a single plate 132 with LEDs 130 mounted to it can be used in both the radiant cooling section 122 and the convective cooling section 124. That is, the single plate 132 with LEDs 130 mounted to it can span the radiant cooling section 122 and the convective cooling section 124.

In the radiant cooling section 122, the respective water-cooled plate 132 (with the LEDs 130 mounted to it) is positioned between the upper cooling wall 126 and the conveyor 108 with the light output from the LEDs 130 directed generally downward towards the upper surface of the solar cells 106 passing by on the conveyor 108.

In the convective cooling section 124, the respective water-cooled plate 132 (with the LEDs 130 mounted to it) is positioned in the upper part of the section 124 above the conveyor 108 with the light output from the LEDs 130 directed generally downward towards the upper surface of the solar cells 106 passing by on the conveyor 108. The portion of the water-cooled plate 132 that is positioned in the convective cooling section 124 has a shape (and/or openings formed it) to enable air flowing through the convective cooling section 124 to pass through and/or around the water-cooled plate 132 and the mounted LEDs 130.

The water-cooled plate 132 can be mounted within the cooling sections 122 and 124 in any suitable manner (for example by attaching, suspending, or supporting the plate 132 and LEDs 130 to one or more of the side, top, or bottom walls of the furnace 100 or one or more structures within the cooling chamber 104 such as the cooling walls 126).

A power supply (not shown) is electrically connected to each of the LEDs 130 in order to provide power to the LEDs 130. In this exemplary embodiment, the power supply is positioned outside of the cooling chamber 104.

The number, size, and arrangement of the LEDs 130 in the array are configured so as to provide sufficiently intense illumination for performing light annealing to reduce LID (for example, by having a radiation intensity in a range between 3,000 Watts/meters² and 48,000 Watts/meters²). For example, in one implementation, 10 millimeter by 10 millimeter LEDs are arranged in an array in which there are at least two thousand LEDs in an area that is about 0.3 meters wide by about 3 meters long. It is to be understood, however, that the LEDs can be arranged in other ways.

In this exemplary embodiment, the LEDs 130 are commercially available LEDs that output light in the spectrum between 300 nanometers and 900 nanometers (that is, within the visible spectrum).

Moreover, one advantage of using LEDs 130 to provide the intense light for light annealing is that the intensity of light output from the LEDs 130 can be adjusted by adjusting the DC voltage supplied to the LEDs 130. This enables the light intensity to be adjusted as needed to optimize the light annealing process.

In the exemplary embodiment shown in FIG. 2, the array of LEDs 130 includes multiple zones 134, where each zone 134 includes a subset of the LEDs 130. In this exemplary embodiment, the intensity of light output by the LEDs 130 in each of the zones 134 can be independently controlled. The zones 134 can be adjusted so that the intensity of light output by the LEDs 130 in at least one of the zones 134 differs from the intensity of light output by the LEDs 130 in at least one of the other zones 134. For example, the temperature of the solar cells 106 will be reduced as the solar cells 106 are conveyed through the cooling chamber 104. As a result, it might be beneficial to adjust the light intensity in the various zones 134 to account for this reduction in temperature as the solar cells are conveyed through the cooling chamber 104.

In general, the process of light annealing for LID reduction can be controlled based on various factors including, without limitation, the speed at which the solar cells 106 are conveyed through the cooling chamber 104, the length of the cooling chamber 104, the length of the array of LEDs 130, the exit temperature of the solar cells 106 as they exit the heating chamber 102 and enter the cooling chamber 104, the intensity of light output from the LEDs 130 in each of the light zones 134 (or the array of LEDs 130 as a whole where zones 134 are not used), and the number, size, and arrangement of the LEDs 130.

In some examples, the LEDs 130 are omitted from the furnace 100, and annealing is instead implemented at a different location in the manufacturing process.

In one implementation, one or more of these factors are controlled so that each solar cell 106 moving through the cooling sections 122 and 124 on the conveyor 108 will be exposed to the intense light from the LEDs 130 for an amount of time between 5 seconds and 45 seconds. In one example, this is done while each solar cell 106 is at a temperature between 700° C. and 240° C. In another example, this is done while each solar cell 106 is at a temperature between 700° C. and 50° C.

The first heating section 114 is configured to generate a number of heating zones 136a-136p above and below the conveyor 108. The example heating zones 136a-136p are individually controlled by the example furnace controller 26 by controlling the lamps 120 associated with the corresponding heating zone 136a-136p. While the example heating zones 136a-136p are illustrated as eight adjacent upper zones 136a-136h and eight adjacent lower zones 136i-136p in FIG. 2, any number and/or arrangement of heating zones may be implemented in the first heating section 114 and/or the second heating section 116. In some examples, one or more of the adjacent heating zones are separated by space that is devoid of heating lamps 120 and/or separated by one or more baffles or other barriers to inhibit transfer of heat between the zones 136a-136p.

The example furnace controller 26 may use heating profiles that define respective temperatures for the heating zones 136a-136p in the furnace 100. The furnace controller 26 may store, load, modify, and/or otherwise use the heating profiles to quickly define the temperatures to be used by the furnace 16.

The tester controller 28 controls the operation of the photovoltaic cell tester 18 and/or collects measurements of the photovoltaic cell properties from the tester 18. In some examples, the tester controller 28 communicates with the furnace controller 26 to correlate measurements to heating profiles implemented by the furnace controller 26. For example, the furnace controller 26 and/or the tester controller 28 may correlate measurement information to sets of the photovoltaic cells based on at least one of a travel speed of the photovoltaic cells on a belt running through the firing furnace 16, a distance from the firing furnace 16 to the photovoltaic cell tester 18, a belt stop signal, a belt start signal, an identification of the sets of the photovoltaic cells received from at least one of the photovoltaic cell tester 18 and/or the firing furnace 16.

The measurement information may include the measured properties for individual cells of a set of photovoltaic cells. Additionally or alternatively, the measurement information may include representative information about the set of photovoltaic cells. For example, the tester controller 28 may determine and provide an average efficiency for a set of photovoltaic cells and the statistical variance of the efficiency within the set of photovoltaic cells.

To correlate the measurement information to the sets of photovoltaic cells, the furnace controller 26 may, for example, determine a start time for a cell batch and/or for a particular heating profile, determine a belt speed and/or a length of the belt to determine a time at which the set of photovoltaic cells will exit the furnace 16, determine a duration of the cell batch and/or the heating profile, and/or determine the expected start time and/or expected end time of the cell batch and/or heating profile with which the measurements are to be correlated. The example furnace controller 26 may provide the expected start time and/or expected end time to the tester controller 28 for correlation of measurement results with test results, and/or the furnace controller 26 may receive measurement results with timestamps, and correlate the measurement results with the cell batch and/or the heating profile based on comparing the timestamps to the expected start time(s) and/or expected end time(s). While an example method of correlating the measurements by the tester 18 to the heating profile are disclosed herein, other methods or techniques may be used, such as positive identification of cells using machine readable identifiers and/or manual input.

Based on correlating the properties of photovoltaic cells to the heating profiles used to generate the photovoltaic cells, the example furnace controller 26 may generate or modify a heating profile to result in improved properties of photovoltaic cells output from the furnace 16. For example, the furnace controller 26 may analyze the heating profiles (e.g., temperature settings for the zones of the furnace 16) based on the resulting cell efficiency metric to determine the appropriate temperature(s) and/or heating profiles at which the photovoltaic cells are to be fired to consistently increase (e.g., maximize or optimize) the cell efficiency metric of produced photovoltaic cells.

In an example, the furnace controller 26 may control the firing furnace 16 fire multiple sets of the solar cells 106 using multiple heating profiles. The fired sets of solar cells 106 are tested by the tester 18 to measure one or more properties of the solar cells 106. The furnace controller 26 and/or the tester controller 28 correlate the one or more properties of the sets of solar cells 106 with the heating profiles used to fire each set. furnace controller 26 and/or the tester controller 28 may use the data to generate one or more heating profiles that result in an improved (e.g., optimized) value for firing the solar cells. As the number of different heating profiles increases, the data that can be used by the furnace controller 26 and/or the tester controller 28 to determine an optimized heating profile also increases and may improve the resulting heating profile.

FIG. 3 is a block diagram of an example computing system 200 that may be used to implement the printer controller 22, the dryer controller 24, the furnace controller 26, and/or the tester controller 28 of FIG. 1. The computing system 200 may be, an integrated computing device in any of the photovoltaic cell printer 12, the photovoltaic cell dryer 14, the photovoltaic cell firing furnace 16, and/or the photovoltaic cell tester 18, a desktop or all-in-one computer, a server, a laptop or other portable computer, a tablet computing device, a smartphone, and/or any other type of computing device.

The example computing system 200 of FIG. 3 includes a processor 202. The example processor 202 may be any general purpose central processing unit (CPU) from any manufacturer. In some other examples, the processor 202 may include one or more specialized processing units, such as RISC processors with an ARM core, graphic processing units, digital signal processors, and/or system-on-chips (SoC). The processor 202 executes machine readable instructions 204 that may be stored locally at the processor (e.g., in an included cache or SoC), in a random access memory 206 (or other volatile memory), in a read only memory 208 (or other non-volatile memory such as FLASH memory), and/or in a mass storage device 210. The example mass storage device 210 may be a hard drive, a solid state storage drive, a hybrid drive, a RAID array, and/or any other mass data storage device.

A bus 212 enables communications between the processor 202, the RAM 206, the ROM 208, the mass storage device 210, a network interface 214, and/or an input/output interface 216.

The example network interface 214 includes hardware, firmware, and/or software to connect the computing system 200 to a communications network 218 such as the Internet. For example, the network interface 214 may include IEEE 202.X-compliant wireless and/or wired communications hardware for transmitting and/or receiving communications.

The example I/O interface 216 of FIG. 2 includes hardware, firmware, and/or software to connect one or more input/output devices 220 to the processor 202 for providing input to the processor 202 and/or providing output from the processor 202. For example, the I/O interface 216 may include a graphics processing unit for interfacing with a display device, a universal serial bus port for interfacing with one or more USB-compliant devices, a FireWire, a field bus, and/or any other type of interface. The example computing system 200 includes a display device 224 (e.g., an LCD screen) coupled to the I/O interface 216. Other example I/O device(s) 220 may include a keyboard, a keypad, a mouse, a trackball, a pointing device, a microphone, an audio speaker, an optical media drive, a multi-touch touch screen, a gesture recognition interface, a magnetic media drive, and/or any other type of input and/or output device.

The example computing system 200 may access a non-transitory machine readable medium 222 via the I/O interface 216 and/or the I/O device(s) 220. Examples of the machine readable medium 222 of FIG. 2 include optical discs (e.g., compact discs (CDs), digital versatile/video discs (DVDs), Blu-ray discs, etc.), magnetic media (e.g., floppy disks), portable storage media (e.g., portable flash drives, secure digital (SD) cards, etc.), and/or any other type of removable and/or installed machine readable media.

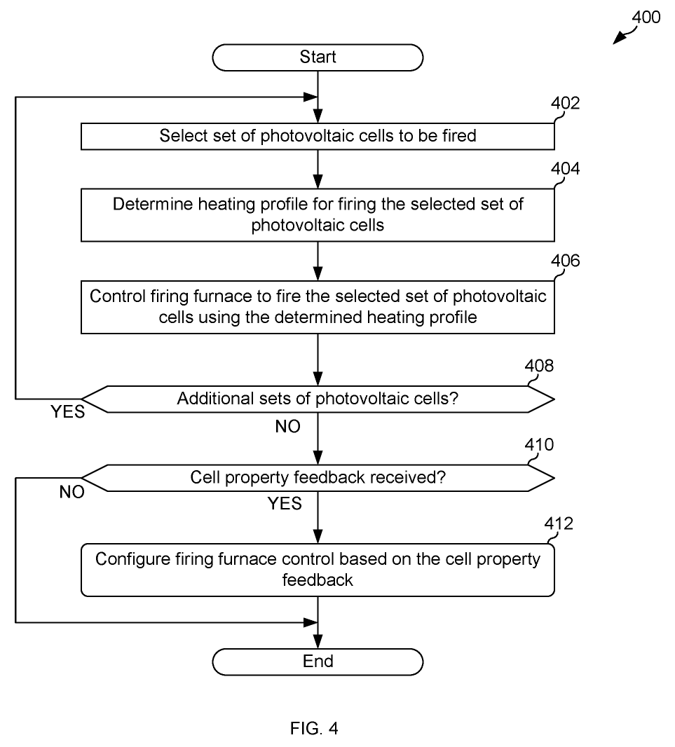

FIG. 4 is a flowchart representative of example machine readable instructions 400 which may be executed by the example furnace controller 26 of FIG. 1 to control a heating profile of the firing furnace 16 of FIG. 1 based on feedback from the tester controller 28. The example instructions 400 are described with reference to the computing system 200 implementation of the furnace controller 26 described with reference to FIG. 3.

At block 402, the processor 202 selects a set of photovoltaic cells to be fired. For example, the processor 202 may receive information about the set of photovoltaic cells from a printer controller 22 and/or a dryer controller 24. At block 404, the processor 202 determines a heating profile for firing the selected set of photovoltaic cells. For example, the processor 202 may select a heating profile that defines temperatures for each of the heating zones 136a-136p. The heating profile may be a production profile (e.g., a best known profile for producing photovoltaic cells), a variant of a production profile (e.g., a heating profile selected to explore improvements to the production profile), one of a set of test heating profiles, and/or any other heating profile. Multiple test heating profiles may be used for corresponding sets of photovoltaic cells to gather data about different test heating profiles and resulting properties of the photovoltaic cells produced using the test heating profiles.

At block 406, the example processor 202 controls the photovoltaic cell firing furnace 16 to fire the selected set of photovoltaic cells using the determined heating profile. At block 408, the processor 202 determines whether there are additional sets of photovoltaic cells to be fired (e.g., using one or more different heating profiles). If there are additional sets of cells to be fired (block 408), control returns to block 402 to select another set of cells.

If there are no more sets of cells to be fired (block 408), at block 410 the example processor 202 determines whether cell property feedback has been received (e.g., from the tester controller 28). Example cell property feedback may include properties for individual cells and/or representative properties of a set of tested photovoltaic cells, such as average values, statistical variance, and/or any other statistical or representative value(s).

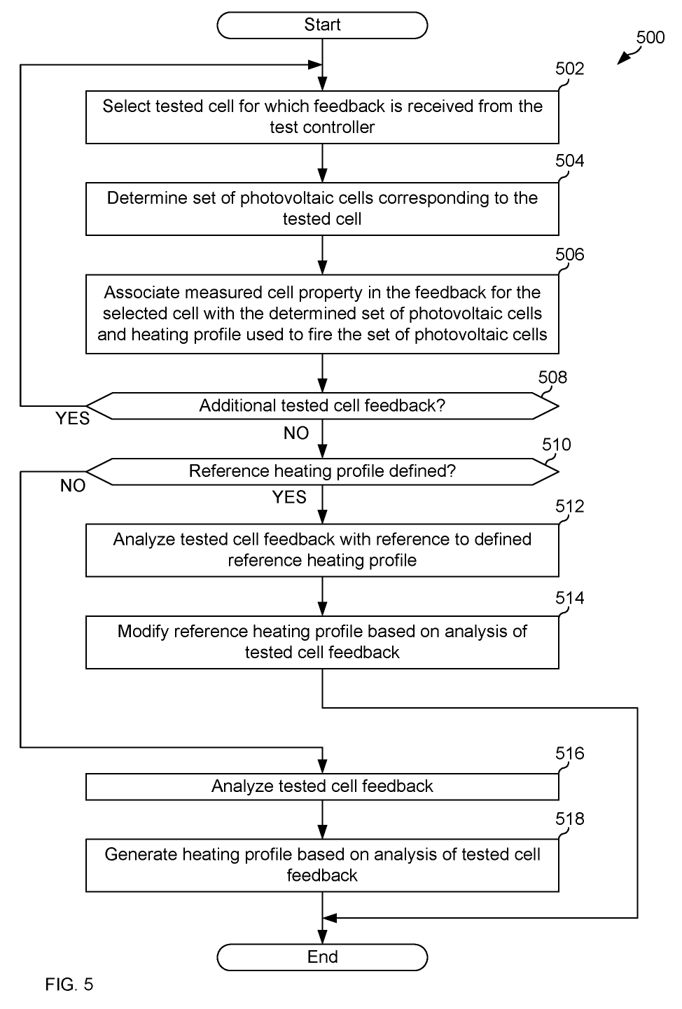

If cell property feedback has been received (block 410), at block 412 the example processor 202 configures control of the firing furnace 16 based on the cell property feedback. For example, the processor 202 may generate and/or modify one or more heating profiles based on test heating profile(s) and/or production heating profile(s) and based on measured cell properties resulting from the test heating profile(s) and/or production heating profile(s). Example instructions to implement block 412 are described below with reference to FIG. 5.

After configuring the control of the firing furnace 16 (block 412), or if no cell property feedback has been received (block 410), the example instructions 400 end.

FIG. 5 is a flowchart representative of example machine readable instructions 500 which may be executed by the example furnace controller 26 of FIG. 1 to modify a heating profile based on the feedback from the cell tester 18. The example instructions 500 may be executed by the processor 202 of FIG. 3 to implement block 412 of FIG. 4.

At block 502, the processor 202 selects a tested photovoltaic cell for which feedback is received from the tester controller 28. At block 504, the processor 202 determines a set of photovoltaic cells corresponding to the tested cell (e.g., an identifiable set or batch of manufactured photovoltaic cells of which the tested cell is a part). For example, the processor 202 may determine an identification of the tested cell for comparison with identifications of cells performed by the furnace controller 26 before, during, or after the time of firing. Additionally or alternatively, the processor 202 may compare a timestamp associated with the tested cell to time periods at which the firing furnace 16 provided sets of photovoltaic cells to the cell tester 18.

At block 506, the processor 202 associates a measured cell property in the feedback for the selected tested cell with the determined set of photovoltaic cells and the heating profile used to fire the determined set of photovoltaic cells. For example, the processor 202 may add the measured cell property as a data point to the set of photovoltaic cells for use in later analysis of heating profiles.

At block 508, the processor 202 determines whether there is additional tested cell feedback received from the tester controller 28. If there is additional tested cell feedback (block 508), control returns to block 502 to select another tested cell. When there is no more tested cell feedback to be associated with a set of photovoltaic cells (block 508), at block 510 the processor 202 determines whether a reference heating profile is defined. For example, the processor 202 may determine whether a production heating profile (e.g., a production recipe, a process of record, etc.) is currently being used and is a reference heating profile to be modified based on test heating profiles (e.g., experimental heating profiles), or a new heating profile is to be generated from a set of test heating profiles.

If a reference heating profile is defined (block 510), at block 512 the processor 202 analyzes the tested cell feedback with reference to the previously defined heating profile (e.g., a production heating profile or recipe). Analysis of the heating profile may involve identifying features from the heating profiles that correspond to desired or improved cell properties, such as cell efficiency.

At block 514, the example processor 202 modifies the defined reference heating profile (e.g., the production profile or recipe) based on the analysis of the tested cell feedback. For example, the processor 202 may modify the temperature of one or more of the zones 136a-136p based on determining that the modified temperatures will (or are likely to) result in improved photovoltaic cell properties.

If a reference heating profile is not defined (block 510), at block 516 the processor 202 analyzes the tested cell feedback. Block 516 may be performed in a similar manner as block 512, but without use of a predefined (e.g., production) heating profile as part of the analysis. Analysis of the heating profile may involve identifying features from the heating profiles that correspond to desired or improved cell properties, such as cell efficiency.

At block 518, the processor 202 generates a heating profile based on analysis of tested cell feedback. For example, the processor 202 may use the test heating profile resulting in the most desirable measured cell properties to generate the heating profile. Additionally or alternatively, the processor 202 may interpolate temperatures for one or more of the heating zones 136a-136p based on identifying ones of the heating zone(s) and/or temperature(s) that result in desirable cell properties from different ones of the test heating profiles.

After generating the heating profile (block 518), or after modifying the current heating profile (block 514), the example instructions 500 may end.

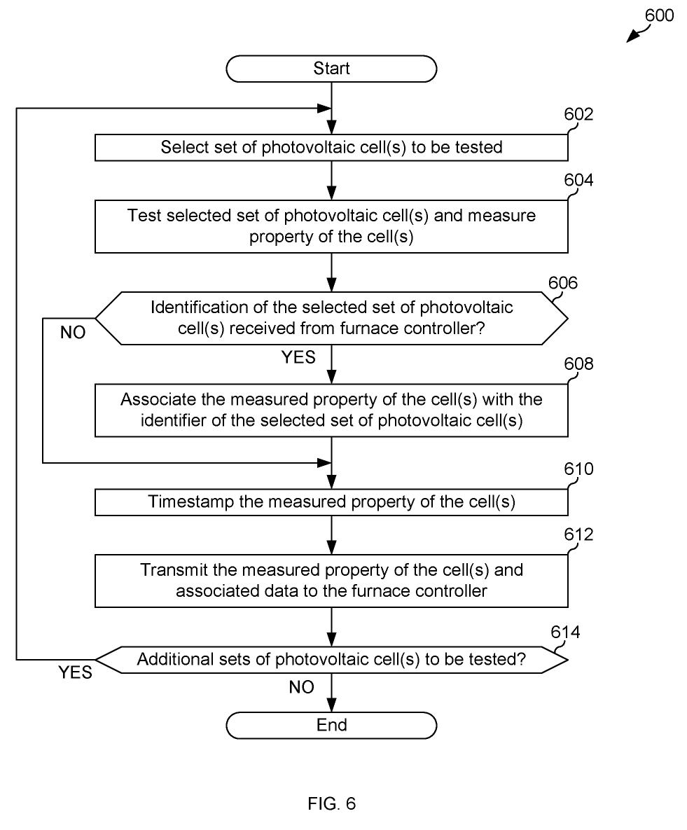

FIG. 6 is a flowchart representative of example machine readable instructions 600 which may be executed by the example tester controller 28 of FIG. 1 to provide feedback about a measured property of photovoltaic cells to the furnace controller 26. The example instructions 600 may be performed by the computing system 200 of FIG. 3 implementing the tester controller 28.

At block 602, the example processor 202 selects a set of photovoltaic cell(s) to be tested. For example, the tester controller 28 may receive an indication from the furnace controller 26 of a set of one or more photovoltaic cells that correspond to a set (e.g., fired using the same heating profile at the firing furnace 16). At block 604, the processor 202 tests the selected set of photovoltaic cell(s) and measures one or more properties of the cell(s). For example, the processor 202 may test one or more of cell conversion efficiency, open-circuit voltage, short-circuit current, maximum cell output power, cell output voltage at the maximum cell power output, cell output current at the maximum cell power output, fill factor, cell diode properties, cell series resistance, cell shunt resistance, and/or any other desired property.

At block 606, the processor 202 determines whether an identification of the selected set of photovoltaic cell(s) has been received from the furnace controller 26. For example, the identification may include a calculated testing time range, a firing time range, and/or a cooling time range of the set of photovoltaic cell(s). Additionally or alternatively, the identification may include a positive identification of the cells, such as serial numbers, a batch number, and/or any other identification that may be recognized at the cell tester 18.

If an identification of the selected set of photovoltaic cell(s) has been received from the furnace controller 26 (block 606), at block 608 the processor 202 associates the one or more measured properties of the cell(s) with the identifier of the selected set of photovoltaic cell(s). After associating the one or more measured properties of the cell(s) with the identifier of the selected set of photovoltaic cell(s) (block 608), and/or if an identification of the selected set of photovoltaic cell(s) has not been received from the furnace controller 26 (e.g., the furnace controller 26 is configured to make the association between the properties and the set of cells) (block 606), at block 610 the example processor 202 timestamps the one or more measured properties of the cell(s).

At block 612, the processor 202 transmits the one or more measured properties of the cell(s) and associated data to the furnace controller 26. The associated data may include the timestamp and/or the identifier of the selected set of the photovoltaic cell(s).

At block 614, the processor 202 determines whether there are additional sets of photovoltaic cell(s) to be tested. If there are additional sets to be tested (block 614), control returns to block 602. When there are no additional sets to be tested (block 614), the example instructions 600 end.

The present methods and systems may be realized in hardware, software, and/or a combination of hardware and software. The present methods and/or systems may be realized in a centralized fashion in at least one computing system, or in a distributed fashion in which different elements are spread across several interconnected computing systems. Any kind of computing system or other apparatus adapted for carrying out the methods described herein is suited. A typical combination of hardware and software may include a general-purpose computing system with a program or other code that, when being loaded and executed, controls the computing system such that it carries out the methods described herein. Another typical implementation may comprise an application specific integrated circuit or chip. Some implementations may comprise a non-transitory machine-readable (e.g., computer readable) medium (e.g., FLASH drive, optical disk, magnetic storage disk, or the like) having stored thereon one or more lines of code executable by a machine, thereby causing the machine to perform processes as described herein. As used herein, the term “non-transitory machine-readable medium” is defined to include all types of machine readable storage media and to exclude propagating signals.

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or”. As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.,” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.).

While the present method and/or system has been described with reference to certain implementations, it will be understood by those skilled in the art that various changes may be made and equivalents may be substituted without departing from the scope of the present method and/or system. For example, block and/or components of disclosed examples may be combined, divided, re-arranged, and/or otherwise modified.

In addition, many modifications may be made to adapt a particular situation or material to the teachings of the present disclosure without departing from its scope. Therefore, the present method and/or system are not limited to the particular implementations disclosed. Instead, the present method and/or system will include all implementations falling within the scope of the appended claims, both literally and under the doctrine of equivalents.

What is claimed is:

1. A photovoltaic cell production system, comprising:
a firing furnace comprising a plurality of zones and a belt configured to transport photovoltaic cells through a sequence of the plurality of zones, the zones comprising firing elements configured to fire a metallization layer of photovoltaic cells by heating the photovoltaic cells in the zones;
a photovoltaic cell tester configured to measure a property of the photovoltaic cells; and
control circuitry configured to control the firing elements based on the property of the photovoltaic cells measured by the photovoltaic cell tester.

2. The system as defined in claim 1, wherein the control circuitry is configured to:
control the firing elements based on a first heating profile for firing a first set of the photovoltaic cells, the first heating profile defining a first set of the respective temperatures of the zones;
control the firing elements based on a second heating profile for firing a second set of the photovoltaic cells, the second heating profile defining a second set of the respective temperatures of the zones;
receive first information representative of the property of the first set of photovoltaic cells from the photovoltaic cell tester;
receive second information representative of the property of the first set of photovoltaic cells from the photovoltaic cell tester; and
determine a third heating profile based on the first information, the second information, the first heating profile, and the second heating profile.

3. The system as defined in claim 2, wherein the control circuitry is configured to correlate the first information to the first set of the photovoltaic cells based on at least one of a travel speed of the belt, a distance from the firing furnace to the photovoltaic cell tester, a belt stop signal, a belt start signal, or a positive identification of the first set of the photovoltaic cells received from at least one of the photovoltaic cell tester, the firing furnace, or the cooling chamber.

4. The system as defined in claim 1, wherein the control circuitry is configured to control the firing elements based on a heating profile for firing a first set of the photovoltaic cells, the heating profile defining a set of the respective temperatures of the zones determined based on respective temperature measurements of the zones.

5. The system as defined in claim 1, further comprising thermocouples configured to measure the temperatures of the zones based on a combination of radiant heating and convective heating.

6. The system as defined in claim 1, wherein the property of the photovoltaic cells measured by the photovoltaic cell tester comprises at least one of an average value of the property for the photovoltaic cells or a statistical variance of the property for the photovoltaic cells.

7. The system as defined in claim 1, wherein the photovoltaic cell tester is configured to measure a plurality of properties of the photovoltaic cells, the plurality of properties comprising at least one of a cell conversion efficiency, an open-circuit voltage, a short-circuit current, a maximum cell output power, a cell output voltage at the maximum cell power output, a cell output current at the maximum cell power output, a fill factor, a cell diode property, a cell series resistance, or a cell shunt resistance.

8. The system as defined in claim 1, further comprising a cooling chamber, wherein the photovoltaic cell tester is configured to measure the property of the photovoltaic cells after the photovoltaic cells are cooled by the cooling chamber.

9. The system as defined in claim 1, wherein the firing elements comprise at least one of radiant heaters or convective heaters.

10. A photovoltaic cell firing furnace, comprising:
a plurality of zones comprising firing elements configured to fire a metallization layer of photovoltaic cells by heating the photovoltaic cells in the zones;
a belt configured to transport photovoltaic cells through a sequence of the plurality of zones; and
control circuitry configured to:
receive feedback information comprising a measured property of the photovoltaic cells; and
control the firing elements based on the property of the photovoltaic cells measured by the photovoltaic cell tester.

11. The photovoltaic cell firing furnace as defined in claim 10, wherein the feedback comprises, for the photovoltaic cells, at least one of cell conversion efficiency, open-circuit voltage, short-circuit current, maximum cell output power, cell output voltage at the maximum cell power output, cell output current at the maximum cell power output, fill factor, cell diode properties, cell series resistance, or cell shunt resistance.

12. The photovoltaic cell firing furnace as defined in claim 11, wherein the control circuitry is configured to:
control the firing elements based on a first heating profile for firing a first set of the photovoltaic cells, the first heating profile defining a first set of the respective temperatures of the zones;
control the firing elements based on a second heating profile for firing a second set of the photovoltaic cells, the second heating profile defining a second set of the respective temperatures of the zones;
receive first information representative of the property of the first set of photovoltaic cells from a photovoltaic cell tester;
receive second information representative of the property of the first set of photovoltaic cells from the photovoltaic cell tester; and
determine a third heating profile based on the first information, the second information, the first heating profile, and the second heating profile.

13. The photovoltaic cell firing furnace as defined in claim 12, wherein the control circuitry is configured to correlate the first information to the first set of the photovoltaic cells based on at least one of a travel speed of the belt, a distance from the firing furnace to the photovoltaic cell tester, a belt stop signal, a belt start signal, or a positive identification of the first set of the photovoltaic cells received from at least one of the photovoltaic cell tester, the firing furnace, or the cooling chamber.

14. A photovoltaic cell tester, comprising:
a test fixture configured to measure a property of a fired photovoltaic cell; and
control circuitry configured to transmit the measured property to a photovoltaic cell firing furnace as feedback information associated with the fired photovoltaic cell.

15. The photovoltaic cell tester as defined in claim 11, wherein the test fixture is configured to measure at least one of cell conversion efficiency, open-circuit voltage, short-circuit current, maximum cell output power, cell output voltage at the maximum cell power output, cell output current at the maximum cell power output, fill factor, cell diode properties, cell series resistance, or cell shunt resistance as the property.
